(19) United States
(12) Patent Application Publication
(10) Pub. No.: US 2011/0222212 A1
(43) Pub. Date: Sep. 15, 2011

(54) ELECTRONIC DEVICE WITH LATCHING MECHANISM

(75) Inventors: SHI-XIN XIAO, Shenzhen City (CN); ZUO-DONG LI, Shenzhen City (CN); CHIH-CHIEH HUANG, Tu-Cheng (TW); HUA-LIN LV, Shenzhen City (CN); CHUNG-YUAN CHEN, Tu-Cheng (TW)

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/782,687

(22) Filed: May 18, 2010

(30) Foreign Application Priority Data
Mar. 11, 2010 (CN) 201010122288.1

(51) Int. Cl. H05K 5/00

(52) U.S. Cl. 361/679.01

(57) ABSTRACT

An electronic device with latching mechanism comprises a cover, a base, and a middle case located between the cover and the base. The cover on edges defines a plurality of protruding tabs each with a through hole. The base defines a plurality of hooks. The middle case on the inner surface defines a plurality of protruding portions corresponding to the protruding tabs of the cover in number and arrangement, and a plurality of limiting portions corresponding to the hooks of the base in number and arrangement. The protruding portions each with an angled surface angling toward the cover are received in the through holes of the cover. The limiting portions engage the hooks of the base.

### BACKGROUND

1. Technical Field

The present disclosure relates to device housings and, more particularly, to a portable electronic device utilizing a latching mechanism tightly connecting a base with a cover.

2. Description of the Related Art

Generally, portable electronic devices, such as mobile phones, include a removable back cover providing access to a battery, a memory card, or other components. The back cover generally includes hooks received in grooves defined in a main body, which constitutes a latching mechanism connecting the back cover to the main body. Although this latching mechanism satisfies basic requirements, an electronic device utilizing a new latching mechanism is called for.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the electronic device with latching mechanism. Moreover, in the drawings, like reference numerals designate corresponding parts throughout the several views.

FIG. 1 is an isometric view of an electronic device with a latching mechanism in accordance with an exemplary embodiment.

FIG. 2 is an exploded view of the electronic device of FIG. 1.

FIG. 3 is a partial enlarged, view of the electronic device of FIG. 2.

FIG. 4 is a partially assembled view of FIG. 3, viewed from another perspective.

FIG. 5 is a partial, assembled, view of the electronic device of FIG. 3.

### DETAILED DESCRIPTION

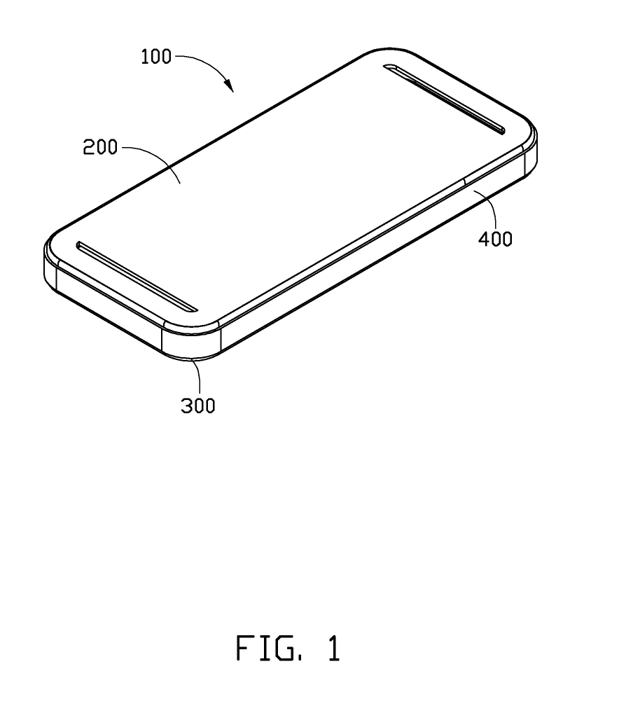

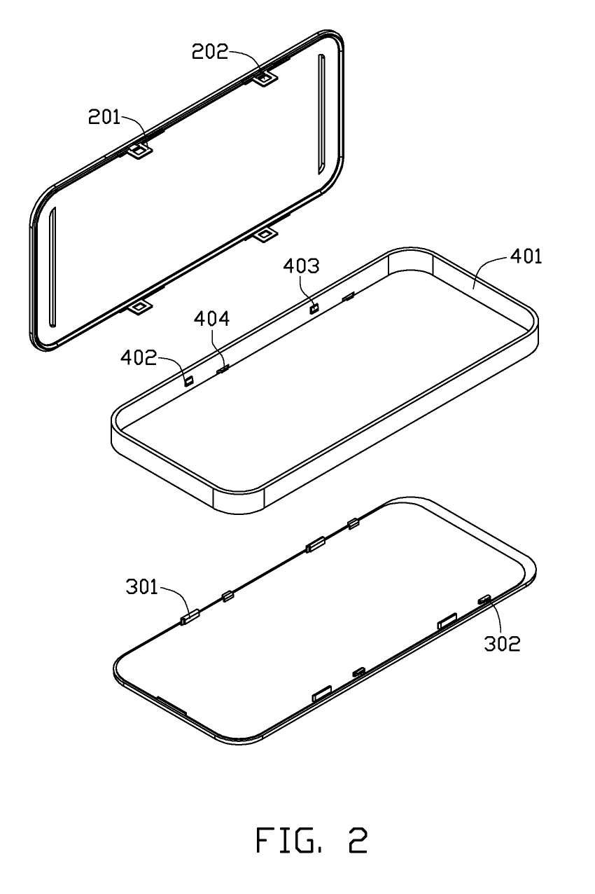

Referring to FIGS. 1-2, an electronic device with latching mechanism 100 includes a cover 200, a base 300, and a middle case 400. The cover 200 and the base 300 are connected together by the middle case 400.

A plurality of protruding tabs 201 on the edges of the cover 200 each defines a through hole 202. In the embodiment, four protruding tabs 201 are deployed. The protruding tabs 201 are made of metal or plastic. Two protruding tabs 201 are on one edge of the cover 200, with the other two on another edge.

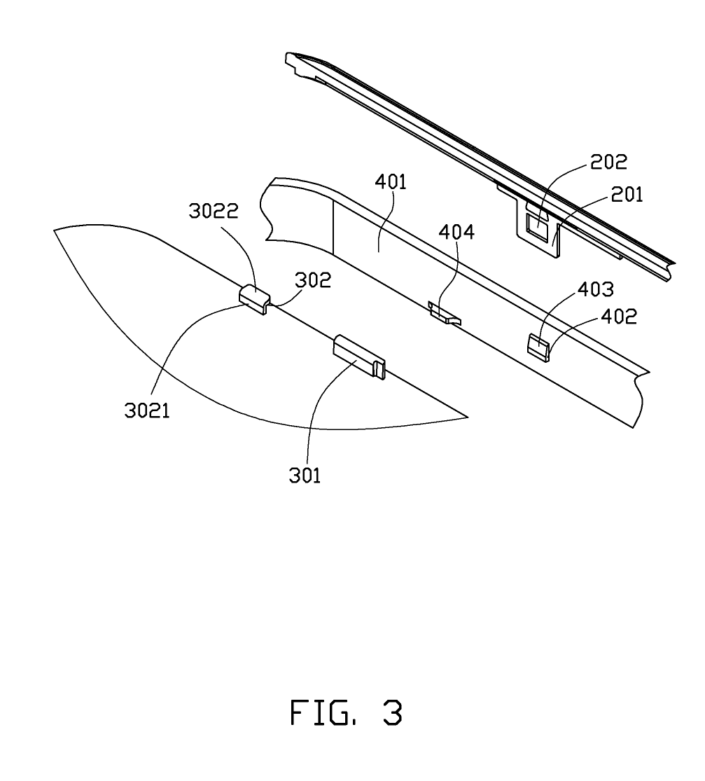

Referring to FIG. 3, an inner surface 401 of the middle case 400 includes a plurality of protruding portions 402. The number and arrangement of the protruding portions 402 match those of the protruding tabs 201 of the cover 200. Each protruding portion 402 includes an angled surface 403 angling toward the cover 200. In the exemplary embodiment, the inner surface 401 of the middle case 400 further includes a plurality of limiting portions 404 protruding therefrom. Four limiting portions 404 are deployed.

The base 300 includes a plurality of resisting portions 301 corresponding to the protruding tabs 201 of the cover 200 in number and arrangement. The resisting portions 301 extend along edges of the base 300. In the exemplary embodiment, the base 300 defines a plurality of hooks 302 corresponding to the limiting portions 404 of the middle case 400 in number and arrangement. Each hook 302 includes a first wall 3021 extending from the bottom of the base 300, and a second wall 3022 extending outwardly from the first wall 3021.

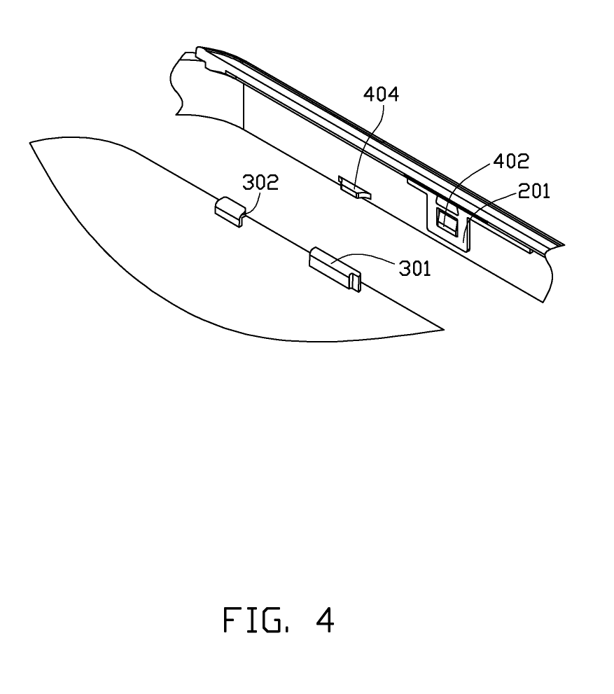

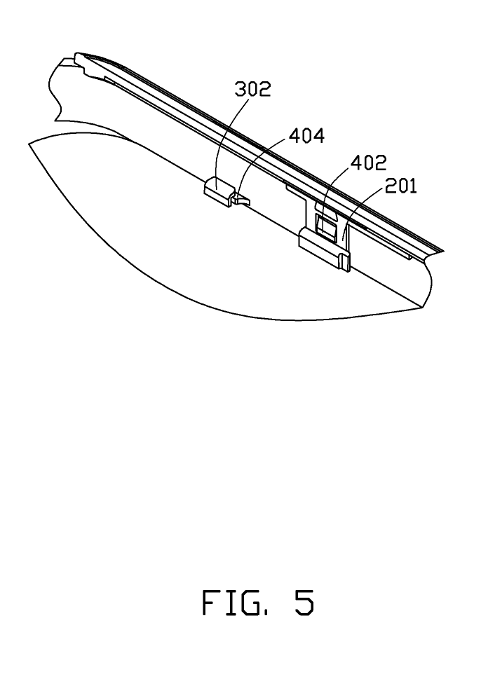

Referring to FIGS. 4-5, during connecting the cover 200 with the base 300, the protruding tabs 201 are first aligned with the protruding portions 402 and the cover 200 is impelled toward the middle case 400, until the protruding portions 402 are received in the through holes 202. Ends of the protruding tabs 201 move along the angled surfaces 403, such that each protruding tab 201 is deflected inwardly until the protruding portion 402 is received in the through hole 202. After that, the base 300 is connected onto the side of the middle case 400 that is opposite to the cover 200. The base 300 is assembled to the middle case 400 with the hooks 302 engaging with the limiting portions 404, thus connecting the base 300 to the middle case 400. Also, the resisting portions 301 resist the protruding tabs 201 which can thus prevent the protruding tabs 201 from disengaging from the protruding portions 402.

Finally, while the present disclosure has been described with reference to particular embodiments, the description is illustrative of the disclosure and is not to be construed as limiting the disclosure. Therefore, various modifications can be made to the embodiments by those of ordinary skill in the art without departing from the true spirit and scope of the disclosure as defined by the appended claims.

What is claimed is:

1. An electronic device with latching mechanism, comprising:
a cover with a plurality of protruding tabs on edges thereof, each protruding tab defining a through hole;
a base with a plurality of hooks; and
a middle case located between the cover and the base, an inner surface of the middle case defining a plurality of protruding portions and limiting portions, each of the protruding portions being received in the through hole of one of the protruding tabs and connecting the cover to the middle case, and each of the limiting portions engaging one of the hooks and connecting the base to the middle case.

2. The electronic device with latching mechanism as described in claim 1, wherein the number of the plurality of protruding tabs is four.

3. The electronic device with latching mechanism as described in claim 2, wherein two protruding tabs are on one edge of the cover, with the other two on another edge.

4. The electronic device with latching mechanism as described in claim 1, wherein the protruding tabs are made of metal or plastic.

5. The electronic device with latching mechanism as described in claim 1, wherein the base further defines a plurality of resisting portions corresponding to the protruding tabs of the cover.

6. The electronic device with latching mechanism as described in claim 1, wherein the plurality of protruding portions each defines an angled surface angling toward the cover.

7. The electronic device with latching mechanism as described in claim 1, wherein each hook comprises a first wall protruding from a bottom of the base, and a second wall protruding outwardly from the first wall.

8. The electronic device with latching mechanism as described in claim 1, wherein the number of the limiting portions is four.
